(19) United States
(12) Patent Application Publication
(10) Pub. No.: US 2026/0328802 A1
(43) Pub. Date: Oct. 22, 2026

(54) DEVICE ASSEMBLY

(71) Applicant: NU NANO LTD., Bristol (GB)

(72) Inventors: Nathan BROCKIE, Bristol (GB); Hannah LEVENE, Bristol (GB); Richard PERRY, Bristol (GB); James VICARY, Bristol (GB)

(73) Assignee: NU NANO LTD., Bristol (GB)

(21) Appl. No.: 19/112,079

(22) PCT Filed: Sep. 20, 2023
(86) PCT No.: PCT/GB2023/052426

§ 371 Date: Mar. 14, 2025

(30) Foreign Application Priority Data
Sep. 20, 2022 (GB) 2213721.0
Sep. 30, 2022 (GB) 2214420.8

(51) Int. Cl. G01Q 60/38; H10P 72/70; H10W 72/00; H10W 72/30

(52) U.S. Cl. CPC G01Q 60/38; H10P 72/7434; H10W 72/07307; H10W 72/385

(57) ABSTRACT

Disclosed is at least a method comprising: providing a source wafer having a leading surface, and on the leading surface is formed a device portion and a support portion; and providing a handling wafer, comprising on a leading surface thereof a first support element arranged to coincide with the device portion and a second support element arranged to coincide with the support portion. Then bringing the leading surface of the source wafer and the leading surface of the handling wafer together, to align the first support element and the device portion, and to align the second support element and the support portion. Then bonding the second support element to the support portion. Then removing material from the opposing surface of the source wafer to expose the device portion, the support portion, and a bridge portion, the bridge portion attaching the device portion to the support portion.

### TECHNICAL FIELD

The present invention relates to assembly of devices and devices so assembled.

### BACKGROUND

It is known to assemble a device by combining a device portion and a host wafer. This allows, for example, the host wafer and the device portion to comprise different materials and/or to be provided by different methods. Improved methods of assembling a device can increase yield, improve the quality of the device and/or reduce the cost of providing the device. Devices that can be assembled in this way include, but are not limited to, semiconductor devices, devices produced by processing of a wafer, devices fabricated on a wafer, micromechanical devices, electrical devices, optical devices, photonic devices, devices produced by lithography, devices produced by etching, Atomic Force Microscopy (AFM) probe devices, mechanical sensor devices, display devices, graphics card devices, motherboard devices, or photovoltaic devices.

### SUMMARY

A first aspect of the present invention provides a method, comprising: providing a source wafer having a leading surface and an opposing surface, and on the leading surface is formed a device portion and a support portion; providing a handling wafer, comprising on a leading surface thereof a first support element arranged to coincide with the device portion and a second support element arranged to coincide with the support portion; bringing the leading surface of the source wafer and the leading surface of the handling wafer together, to align the first support element and the device portion, and to align the second support element and the support portion; bonding the second support element of the handling wafer to the support portion of the source wafer; removing material from the opposing surface of the source wafer to expose the device portion, the support portion, and a bridge portion, the bridge portion attaching the device portion to the support portion, the support portion remaining bonded to the second support element.

In examples, the device portion is indirectly attached by the bridge portion, second support element and the support portion to the handling wafer. This is done by bonding of the second support element to the support portion. The resulting bond may reduce unwanted rotation and/or displacement of the device portion with respect to the handling wafer. Reduced rotation and/or displacement can increase the yield of the device and/or increase the performance of the device. At least one of the first support element, the second support element, or the support portion may be configured so that it prevents contact between the source wafer and the handling wafer.

In any event, in examples, no or substantially no bonding occurs between the device portion and the first support element.

Bonding herein may comprise at least one of chemical bonding, adhesion, or vacuum bonding.

In examples described herein, a device is an object manufactured, produced, fabricated or assembled for the performance of a purpose. A device may be at least one of a semiconductor device, a device produced by processing of a wafer, a device fabricated on a wafer, a micromechanical device, an electrical device, an optical device, a photonic device, a device produced by lithography, or a device produced by etching. A device, for example, may be at least one of: a display device for displaying an image, an electronic integrated circuit (IC) device for a computing, a probe device for AFM; a photovoltaic device for photodetection; a photonic integrated circuit (PIC) for producing a laser beam; an optical device for telecommunications; a probe for detecting nuclear radiation; a microelectromechanical system (MEMS; or a membrane-based sensor device used, for example, in measuring acceleration. Other devices are envisaged.

The methods described herein relate to the production or assembly of device portions that become or are used in the formation of devices. It may be desirable to reduce the size of device portions fabricated on a wafer to increase the density of device portions on the wafer thereby increasing the number of device portions that can be fabricated on a single wafer. In some examples, the fabrication plants wherein wafers are fabricated use a fixed wafer size, for example, at least one of a: 25 millimetre, 51 millimetre, 76 millimetre, 100 millimetre, 200 millimetre, or 300 millimetre diameter silicon wafers. Consequently, increasing the device portion density for a wafer is desirable. It may be desirable to attach a small device portion to a larger device portion or device, for example, attaching a small IC to a circuit board to form a sensor device.

More-precisely aligning the device portion and a mounting portion of a host wafer to receive the device portion can lead to increased yield of assembled devices, improved quality of the device produced by the method of examples, and/or reduced cost of providing the device. If a device portion is misaligned with a mounting portion of a host wafer of the device, for instance, the device in some examples may not function with sufficient performance to be of commercial value or may not function at all. As will be described, misalignment of the device portion can be a result of a weak bond between the device portion and a handling wafer being used to align the device portion with the surface as the weak bond may permit undesirable movement of the device portion with respect to the handling wafer. It has been found that indirectly attaching the device portion to the handling wafer (the device portion connected by a bridge portion to a support portion that is bonded to the second support element of the handling wafer) can reduce movement and/or misalignment of the device portion. In some examples, bonding the support portion to the handling wafer (and not directly bonding the device portion to the handling wafer) can increase the precision and reliability of positioning of the device increases yield and/or performance of the device. Bonding the support portion to the handling wafer can reduce undesired displacement or rotation of the device portion with respect to the handling wafer that may occur during assembly of the device. Consequently, likelihood of misalignment of the device portion may be reduced.

According to examples herein, a device portion is a portion of a device. For example, a device portion may be: a polymer sphere or a paddle structure for example for a device, such as an AFM probe device; a sensor of a mechanical device; a micro light emitting diode (LED) for a display device; or a photovoltaic cell for a solar panel device. In further examples, a device portion may be at least one of: a probe; a PIC; a polymer sphere; an IC; a MEMS; a conductive layer; a conductive bridge; an electrode; a reflector; or a sensor. In some examples, the device portion comprises (without limitation) at least one of: a glass, a dielectric, a polymer, silicon, gallium, germanium, lithium niobate, carbon, indium, or an alloy of at least one of the foregoing. Other elements and/or materials are envisaged.

According to examples herein, a source wafer is a wafer comprising a leading surface having a device portion formed thereon. The source wafer may be a crystalline silicon wafer. The device portion may be (without limitation) at least one of: part of or an entire AFM probe or an IC formed on the leading surface of the source wafer. In some examples, the source wafer comprises (without limitation) at least one of: a glass, a dielectric, a polymer, silicon, gallium, germanium, lithium niobate, carbon, indium, or an alloy of at least one of the foregoing. Other elements and/or materials are envisaged.

According to examples herein, a wafer may also be referred to as a slice, a substrate or a layer. The term wafer is used herein to denote a relatively thin portion of material and in some examples is crystalline. A wafer may be a disc of crystalline silicon for use in a semiconductor fabrication plant. Inn some such examples a wafer is at least one of: a 25 millimetre, 51 millimetre, 76 millimetre, 100 millimetre, 200 millimetre, or 300 millimetre disc.

According to examples herein, a support portion may be a portion on or supported by the source wafer. The support portion is configured for bonding to the second support element. The support portion may comprise material and/or a coating to aid bonding. The coating and/or material may allow the formation of a bond, such as a chemical bond and/or a mechanical bond, to attach the support portion to the second support element. The support portion may comprise (without limitation) at least one of: a glass, a dielectric, a polymer, silicon, gallium, germanium, lithium niobate, carbon, indium or an alloy of at least one of the foregoing. Other elements and/or materials are envisaged.

Optionally, the method comprises providing the device portion, and/or the first support element, such that the step of bonding the second support element of the handling wafer to the support portion of the source wafer causes no or at least reduced bonding of the device portion to the first support element.

In examples, no, substantially no or at least reduced bonding of the device portion to the first support element during the step of bonding the second support element to the support portion may reduce the impact of the method on the device and/or allow the use of fragile device portions.

In some examples, the device portion and/or the first support portion comprises a material and/or a coating to inhibit bonding such that the step of bonding the second support element of the handling wafer to the support portion of the source wafer causes no or at least reduced bonding of the device portion to the first support element. The coating and/or material may prevent the formation of a chemical bond to attach the first support element to the device portion. The first support element may comprise (without limitation) at least one of: a glass, a dielectric, a polymer, silicon, gallium, germanium, lithium niobate, graphene, indium, or an alloy of at least one of the foregoing. Other elements and/or materials are envisaged.

A handling wafer according to examples herein is a wafer for handling or supporting the first support element and the second support element. The handling wafer may be a glass wafer. The handling wafer may support the first support element and the second support element. In some such examples, at least one of the first support element or the second support element comprises a glass. The first support element may be coated to prevent bonding to the device portion and/or the second support element may be coated to aid bonding to the support portion. In some examples, the handling wafer comprises (without limitation) at least one of: a glass, a dielectric, a polymer, silicon, gallium, germanium, lithium niobate, carbon, indium, or an alloy of at least one of the foregoing. Other elements and/or materials are envisaged.

Removing material according to examples herein may comprise at least one of etching, polishing or grinding.

A bridge portion according to examples herein is a portion attaching the device portion to the support portion. In some examples, the bridge portion is part of the same material or of the same material as at least one of the device portion or the support element. In other examples, the bridge portion is not part of the same material or of the same material as at least one of the device portion or the support element. The bridge portion can substantially prevent the translation, rotation and/or the misalignment of the device portion with respect to the support portion, for example, during bonding, processing or handling.

Optionally, the device portion is supported by the first support element while bonding the second support element of the handling wafer to the support portion of the source wafer; and/or removing material from the opposing surface of the source wafer.

In examples, supporting the device portion during the bonding stage, and/or the removing stage may allow the reduction in damage to the device portion during the stage or stages. Supporting the device portion may reduce unwanted rotation and/or displacement of the device portion with respect to the handling wafer. In some examples supporting the device portion may prevent contact between the device portion and an undesirable portion the handling wafer or allow the setting the separation between the handling wafer member and the device portion.

Optionally, the method comprises: providing a host wafer, the host wafer comprising a leading surface with a mounting portion arranged to coincide with the device portion; bringing together and aligning the mounting portion with the device portion; bonding the device portion to the mounting portion; and breaking the bridge portion, thereby separating the device portion from the handling wafer, such that the device portion is carried by the host wafer.

Examples may allow the bonding of a device portion smaller than other methods, the device portion may be less than at least one of 10 millimetre, 1 millimetre, 100 micrometres or 10 micrometres in a diameter parallel to the contact between the device portion and the surface, device portions less than at least one of 10 millimetre, 1 millimetre, 100 micrometres, 10 micrometres or 1 micrometre in a thickness measured perpendicular to the contact between the device portion and the surface, without breaking or shearing the device portion.

In examples, a host wafer may be a wafer that provides a substrate for the assembly or fabrication of a device. In examples, the host wafer may be provided by a multi-step process of providing a mask on the wafer; at least one of depositing the layer on the wafer or removing a portion of the wafer; and at least partly removing the mask. In this example, only three stages are mentioned but more stages may be involved. This may allow modification of the topography of the host wafer to provide additional functionality or to modify the mounting portion, for example, to raise or lower the mounting portion with respect to the rest of the wafer. The removal of a portion of the host wafer may facilitate the separation of the device portion and the host wafer, for example, by the inclusion of holes or grooves in the host wafer.

In examples, breaking the bridge portion may comprise applying a mechanical force, directly or indirectly, to at least one of the host wafer, the handling wafer, the support portion, or the device portion. The bridge portion may be broken using a chemical or electrostatic process, such as by application of an etchant or an electrical potential difference to at least one of the support portions, or the device portion. The bridge portion may be broken by at least one of: dicing of the bridge portion, breaking through stress, or etching at least part of the bridge portion. The bridge portion can be fragile or susceptible to etching or lithography to simplify the breaking of the bridge portion or to reduce the damage or risk of damage to other parts such as the device portion.

In examples, breaking the bridge portion may facilitate the removal of the handling wafer from the device portion. The handling wafer may be re-usable.

In examples the mounting portion and the device portion may be aligned using at least one of: physical guides, computer vision, or image recognition.

In examples, control of the height of the mounting portion (where height is measured perpendicularly to a contact plane between the mounting portion and the device portion) may be used to control a separation between the device portion and a portion of the host wafer. This may allow control of the interactions between the device portion and the portion of the host wafer, or the functionality of the device. For example, the portion of the host wafer may be chemically reactive or electrically active and, consequently, it may be desirable to increase the separation between the portion of the host wafer and the device portion to reduce undesired electrical or chemical interactions.

In examples, the method may be used for high-speed, high-precision, or massively parallel assembly of a device portion or portions. The method can allow the assembly of compound devices, for example, a silicon photonic device comprising a gallium arsenide device portion.

Optionally, the device portion is supported by the first support element when at least one of: bringing together aligning the mounting portion with the device portion; bonding the device portion to the mounting portion; or breaking the bridge portion.

In examples, supporting the device portion during the bringing together and aligning step, the bonding step and/or the breaking step may allow the reduction in damage to the device portion during the stage or stages. Supporting the device portion may reduce unwanted rotation and/or displacement of the device portion with respect to the handling wafer. In some examples supporting the device portion may prevent contact between the device portion and an undesirable portion the handling wafer or allow the setting the separation between the handling wafer member and the device portion.

Optionally, bringing together and aligning the mounting portion with the device portion comprises optically imaging the device portion and at least part of the host wafer, the optical imaging being at least partly through the handling wafer.

In examples, the method may comprise optical imaging at least partly through the handling wafer which may be used to align the device portion and the mounting portion. This may reduce or allow compensation for unwanted rotation and/or displacement of the device portion with respect to the mounting portion. Reduced unwanted rotation and/or displacement can increase the yield of the device and/or increase the performance of the device. A glass handling wafer may allow imaging through the handling wafer. The imaging may be performed using optical radiation. Optical radiation comprises infrared, visible and/or ultraviolet light. Accordingly, the handling wafer may be transparent or translucent at the wavelength of the optical radiation, or comprise a hole or void to allow imaging through the handling wafer.

Optionally, the host wafer comprises handling portion and a bridge element, the bridge element connecting the mounting portion to the handling portion, and the method comprises breaking the bridge portion, thereby separating the handling portion from the mounting portion and the device portion.

In examples, providing a handling portion of the host wafer may simplify the method and/or processing of the host wafer. The separation of the host wafer from the handling portion may allow the device to be smaller. In some examples the handling portion allows easier packaging and transport of the device, in some such examples the bridge element is broken by a user of the device.

Optionally, a surface of the mounting portion comprises an optical reflector and/or an adhesive.

In examples, the mounting portion may have an optical reflector on or in contact with it and/or applied to it. The optical reflector, for example, provides a reflective functionality to the device. The reflective functionality may allow the detection of deflection of an AFM cantilever for an AFM probe device, conversion of a transmissive spatial light modulator (SLM) into a reflective SLM, or photo-thermal actuation of a MEMS switch. Devices requiring an optical functionality may be imaging or display devices, telecommunications devices, sensors, and biomedical devices, although other devices are envisaged. In addition to or instead of the optical reflector, the surface may comprise or support an adhesive. The adhesive may simplify the attaching of the device portion to the mounting portion. In some such examples, the adhesive is also an optical reflector. An example of such is gold, which can be used for both gold thermocompression and (if of sufficient thickness) as an optical reflector. A combined adhesive and optical reflector may simplify assembly of the device. At least one of: at least part of the host wafer that is in contact with the mounting portion, and/or the device portion, is configured so that optical radiation may be incident on the optical reflector. The host wafer or device portion may comprise a hole, be at least partly optically transparent and/or be optically translucent. The multiple functionalities of the gold of the mounting portion may improve and/or simplify the assembly of the device. More generally, diffusion bonding, including gold thermocompression bonding, and bonding using other materials, such as copper or aluminium, may be used to form the bond.

In examples, the first support element may support the device portion as pressure is applied to the support portion and the second support element to form the bond.

In examples, the optical reflector may be a reflector that reflects greater than half of the optical radiation of a given wavelength incident upon it. An optical reflector may be a surface or a portion that is arrange, configured and/or otherwise intended for the reflection of optical radiation.

Optionally, the device portion comprises a first support member and a second support member, and the method comprises bonding the first support member and the second support member to the mounting portion to form a MEMS.

In examples, the device portion may be attached to the surface to form a MEMS. This may allow the formation of a MEMS such as a membrane sensor without using a conventional technique such as a vapour undercut.

Optionally, at least one of the device portion or the host wafer comprises at least part of a further mounting portion to receive a further device portion, the further device portion different to the device portion, and the method further comprises: providing a further source wafer supporting the further device portion; and attaching the further device portion to the further mounting portion.

In examples, the method of assembling a device may comprise attaching a further device portion to the host wafer to form the device. The attaching of a plurality of device portions may allow the assembly of a device with increased functionality, multiple functionalities, or increased performance. This may allow the assembly of more complex devices. In examples, the device portion and the further device portion may be substantially the same or substantially different. The inclusion of two identical device portions, such as identical lasers, may allow an increased performance, such as due to increased output laser power from the device. Multiple similar or identical device portions can also allow increased functionality, for example increased output laser power may allow the device for be used for more applications, such as telecommunications.

In examples, a plurality of devices may be assembled by the method of assembling a device, for example in parallel. This may allow a higher rate of assembly of a plurality of devices or allow the parallel assembly of a plurality of devices using a single assembly. Such a method may be referred to as a massively parallel assembly.

A second aspect of the present invention provides a method, comprising: providing a source wafer having a leading surface and an opposing surface, and on the leading surface is formed a plurality of device portions and a first support structure; providing a handling wafer, comprising on a leading surface thereof a second support structure arranged to coincide with the plurality of device portions and a third support structure arranged to coincide with the first support structure; bringing the leading surface of the source wafer and the leading surface of the handling wafer together, to align the second support structure and the plurality of device portions, and to align the first support structure and the third support structure; bonding the third support structure to the first support structure; removing material from the opposing surface of the source wafer to expose each device portion of the plurality of device portions, the first support structure, and a plurality of bridge portions, a plurality of bridge portions each attaching a respective device portion of the plurality of device portions to the first support structure, the first support structure remaining bonded to the third support structure.

Similar to the situation described for a device portion of the first aspect, a plurality of device portions may be indirectly attached to the handling wafer. This is achieved by each of the device portions being respectively attached to the first support structure by a bridge portion of the plurality of bridge portions, and the first support structure being attached to the handling wafer by bonding of the first support structure to the third support structure. The resulting bond may reduce unwanted rotation and/or displacement of the plurality of device portion with respect to the handling wafer. As has been described, reduced rotation and/or displacement can increase the yield of the plurality of devices device and/or increase the performance of the plurality of devices. At least one of the first support structure, the second support structure, or the third support structure may be configured so that it prevents contact between the source wafer and the handling wafer.

In any case, no or substantially no bonding occurs between the plurality of device portions and the second support structure.

According to examples herein, a support structure comprises at least one of a support portion, a support element, a plurality of support elements or a plurality of support portions.

Optionally, the method comprises providing each device portion of the plurality of device portions, and/or the second support structure, such that the step of bonding the third support structure to the first support structure causes no or at least reduced bonding of the plurality of device portions to the second support structure.

Similar to the situation described for the first aspect of the invention, no, substantially no or at least reduced bonding of the plurality of device portions to the second support structure during the step of bonding the third support structure to the first support structure may reduce the impact of the method on the plurality of devices and/or allow the use of fragile device portions.

In some examples, the plurality of device portions and/or the second support structure comprises a material and/or a coating to inhibit bonding such that the step of bonding the third support structure to the first support structure causes no or at least reduced bonding of the plurality of device portions to the second support structure The coating and/or material may prevent the formation of a chemical bond to attach the first support element to the device portion. The first support element may comprise (without limitation) at least one of: a glass, a dielectric, a polymer, silicon, gallium, germanium, lithium niobate, carbon, indium, or an alloy of at least one of the foregoing. Other elements and/or materials are envisaged.

Optionally, the method comprises providing a host wafer, comprising a leading surface with a plurality of mounting portions each arranged to respectively coincide with a device portion of the plurality of device portions; bringing together and aligning the plurality of mounting portions with the plurality of device portions; bonding each device portion of the plurality of device portions to the respective mounting portion of the plurality of mounting portions; breaking the plurality of bridge portions, thereby separating the plurality of device portions from the handling wafer, such that the plurality of device portions are carried by the host wafer.

Optionally, a thickness of a first device portion of the plurality of device portions is different to a thickness of a second device portion of the plurality of device portions, each thickness measured perpendicular to the respective mounting portion of the plurality of mounting portions.

In other words, in some examples, the device portions of the plurality of device portions are not all the same thickness, wherein the thickness is the height of the device portion on the host wafer. This may allow the method to provide devices of different thicknesses and/or heights.

Optionally, the second support structure comprises a plurality of support elements, each respectively arranged to coincide with a device portion of the plurality of device portions.

Optionally, the plurality of device portions are each respectively supported by a support element of the plurality of first support elements of the second support structure when at least one of: bonding the third support structure to the first support structure; removing material from the opposing surface of the source wafer to expose each device portion of the plurality of device portions, the first support structure, and a plurality of bridge portions, a plurality of bridge portions each attaching a respective device portion of the plurality of device portions to the first support structure, the first support structure remaining bonded to the third support structure; bringing together and aligning the plurality of mounting portions with the plurality of device portions; bonding each device portion of the plurality of device portions to the respective mounting portion of the plurality of mounting portions; or breaking the plurality of bridge portions, thereby separating the plurality of device portions from the handling wafer, such that the plurality of device portions are carried by the host wafer.

In examples, supporting the plurality of device portions during the bonding steps, the aligning step and/or the breaking step may allow the reduction in damage to the plurality of device portions during the step or steps. Supporting the plurality device portion may reduce unwanted rotation and/or displacement of the plurality of device portions with respect to the handling wafer. In some examples supporting the plurality of device portions may prevent contact between the plurality of device portions and an undesirable portion the handling wafer or allow the setting the separation between the handling wafer member and the device portion.

Optionally, a thickness of a first support element of the plurality of support elements of the second support structure, is different to a thickness of a second support element of the plurality of support elements of the second support structure, each thickness measured perpendicular to the leading surface of the handling wafer thickness measured perpendicular.

Optionally, the sum of the thickness of the first device portion of the plurality of device portions, and the thickness of the first support element of the plurality of support elements of the second support structure, is equal to the sum of the thickness of the second device portion of the plurality of device portions, and the thickness of the second support element of the plurality of support elements of the second support structure.

Optionally, at least one of the plurality of device portions or the host wafer comprises at least part of a plurality of further mounting portions each respectively to receive a further device portion of a plurality of further device portions, the plurality of further device portions different to the plurality of device portions, and the method further comprises: providing a further source wafer supporting the plurality of further device portions; and respectively attaching each of the plurality of further device portions to a mounting portion of the further mounting portion.

Optionally, each of the plurality of device portions comprise a first support member and a second support member, and the method comprises bonding each of the first support members and the second support members to the respective mounting portions of the plurality of mounting portions to form a plurality of MEMS.

Optionally, bringing together and aligning the plurality of mounting portions with the plurality of device portions comprises optically imaging a device portion of the plurality of device portions and at least part of the host wafer, the optical imaging at least partly through the handling wafer.

Optionally, the host wafer comprises handling portion and a plurality of bridge elements, the plurality of bridge elements each respectively connecting a mounting portion of the plurality of mounting portions to the handling portion, and the method comprises breaking the plurality of bridge elements, thereby separating the handling portion from the plurality of mounting portions and the plurality of device portions.

In examples, the plurality of device portions may be separated from the handling portion one-by-one by a user when required.

Optionally, a surface of each mounting portion of the plurality of mounting portions respectively comprises an optical reflector and/or an adhesive.

Optionally, the first support structure comprises a plurality of support elements and the third support structure comprises a plurality of support elements, and the plurality of support elements of the first support structure are each respectively arranged to coincide with a support element of the third support structure.

Optionally, bonding and/or attaching comprises at least one of: forming a chemical bond, fusion bonding, gold thermocompression, glass frit bonding, eutectic bonding, soldering, adhesive bonding, or anodic bonding.

In some examples, bonding and/or attaching comprises using an adhesive to mechanically and/or chemically adhere. Further, bonding and/or attaching may comprise: thermal processing, photocuring, exposure to a catalyst, and/or application of pressure.

In examples, at least one of the device portion, the source wafer, or the host wafer may comprise a semiconductor material. A semiconductor material may allow the provision of a semiconductor device.

Optionally, at least one of: the device portion, the source wafer, or the host wafer, comprises (without limitation) at least one of: a glass, a dielectric, a polymer, silicon, gallium, germanium, lithium niobate, carbon, indium or an alloy of at least one of the foregoing. Other elements and/or materials are envisaged.

Optionally, the method comprises the inverting at least one of the source wafer, the handling wafer, or the host wafer.

In other words, in some examples, the method is an inverted method or a flip-chip method. An assembly for an inverted method may be smaller than an assembly for a similar method not comprising an inversion.

A third aspect of the present invention provides a device obtained by the method of the first aspect of the present invention.

A fourth aspect of the present invention provides an assembly obtained by the method of the first aspect of the present invention, the assembly comprising the source wafer and the handling wafer, wherein the second support element of the handling wafer is bonded to the support portion of the source wafer.

A fifth aspect of the present invention provides a plurality of devices obtained by the method of the second aspect of the present invention.

A sixth aspect of the present invention provides an assembly obtained by the method of the second aspect of the present invention, the assembly comprising the source wafer and the handling wafer, wherein the third support structure is bonded to the first support structure.

A seventh aspect of the present invention provides a method of assembling a device or a plurality of devices, the method comprising the method of the first aspect of the invention or the method of the second aspect of the invention.

In examples, a plurality of devices may be assembled by the method of the first aspect of the invention or the second aspect of the invention, for example in parallel. This may allow a higher rate of assembly of a plurality of devices or allow the parallel assembly of a plurality of devices using a single assembly. Such a method may be referred to as a massively parallel assembly.

### BRIEF DESCRIPTION OF THE DRAWINGS

FIG. 1A is a flow diagram that illustrates schematically a method in accordance with examples;

FIG. 1B is a flow diagram that illustrates schematically stages of a method in accordance with further examples;

FIGS. 2A, 2C, 2D, 2F, 2H and 21 are schematic block diagrams that each illustrate a first side cross-section of sequential stages of a method according to examples;

FIGS. 2B, 2E, and 2G are schematic block diagrams that each illustrate a plan view of FIGS. 2A, 2D, and 2F respectively;

FIG. 2J is a schematic block diagram that illustrates a first side cross-section of a device provided by a method of the examples of FIGS. 2A to 21;

FIGFIG. 2K is a schematic block diagram that illustrates a plan view of FIG. 2J;

FIGS. 3A and 3B are schematic block diagrams that each illustrate a plan view of sequential stages of a method according to further examples, FIG. 3B also illustrates a device provided by a method of the examples of FIGS. 3A and 3B;

FIGS. 4A to 4C are a schematic block diagrams that illustrate schematically a first side cross-section of sequential stages of a method according to further examples, FIG. 4C also illustrates the device provided by a method of the examples of FIGS. 4A to 4C;

FIGS. 5A to 5C are schematic block diagrams that each illustrate schematically a plan view of a device of further examples;

FIG. 6 is a flow diagram that illustrates schematically additional stages of a method in accordance with further examples;

FIGS. 7 to 10A are schematic block diagrams that each illustrate schematically a plan view of devices of further examples;

FIG. 10B is a schematic block diagram that illustrates schematically a first side cross-section of the device of 10A;

FIGS. 11A, 11C, 11D, 11F, and 11H to 11J are schematic block diagrams that each illustrate a first side cross-section of sequential stages of a method according to examples;

FIGS. 11B, 11E, and 11G are schematic block diagrams that each illustrate a plan view of FIGS. 11A, 11D, and 11F respectively;

FIG. 11J is a schematic block diagram that each illustrates a first side cross-section of a device provided by a method of the examples of FIGS. 11A to 111;

FIG. 11K is a schematic block diagram that illustrates a plan view of FIG. 11J;

FIG. 11L is a flow diagram that illustrates schematically a method in accordance with further examples;

FIG. 11M is a flow diagram that illustrates schematically stages of a method in accordance with further examples;

FIGS. 12A and 12B are schematic block diagrams that each illustrate a plan view of sequential stages of a method according to further examples, FIG. 12B also illustrates a device provided by a method of the examples of FIGS. 11A and 11B;

FIGS. 13A to 13D are schematic block diagrams that each illustrate a first side cross-section of sequential stages of a method according to examples;

FIG. 13E is a schematic block diagram illustrates a first side cross-section of a device provided by a method of the examples of FIGS. 13A to 13;

FIGS. 14A to 14E are schematic block diagrams that each illustrate a plan view of a source wafer, a handling wafer, a host wafer, a first host wafer and a second host wafer of further examples, respectively.

### DETAILED DESCRIPTION

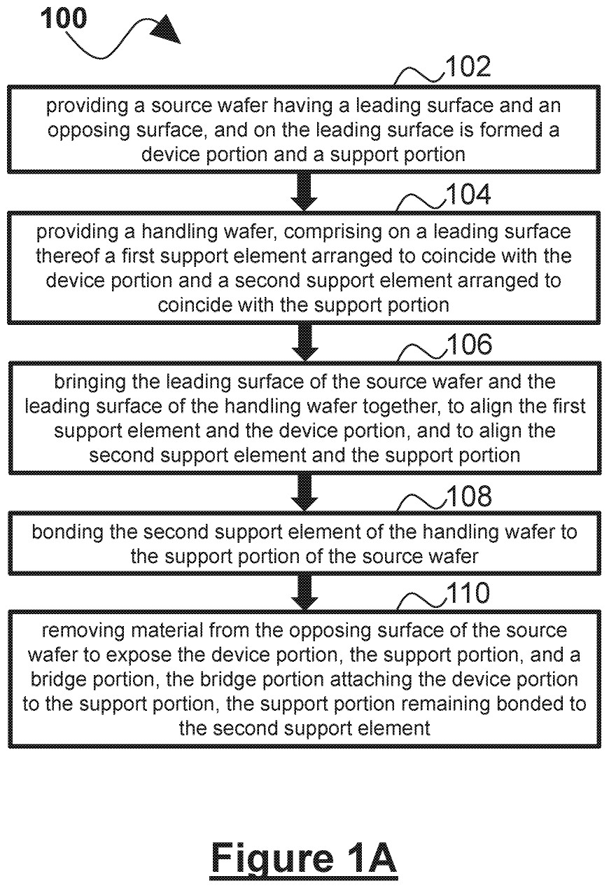

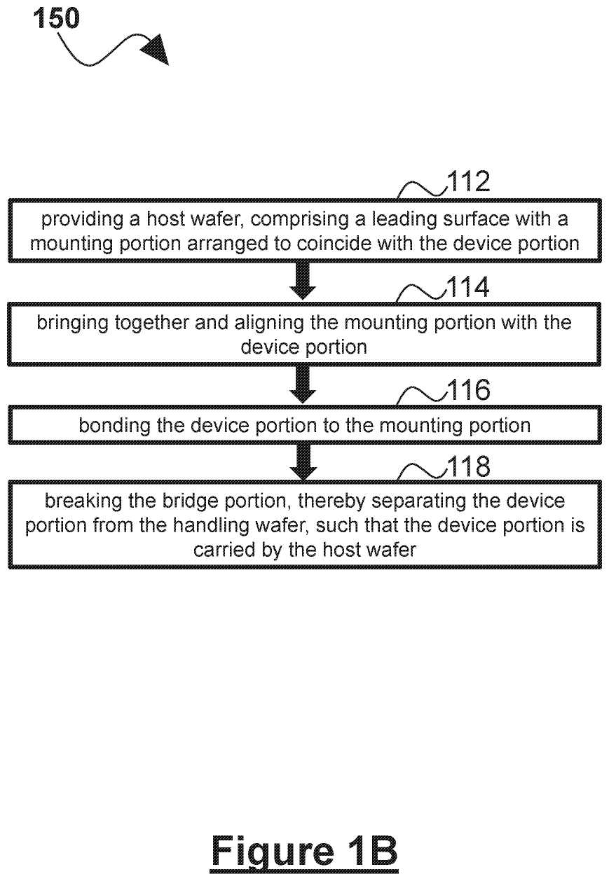

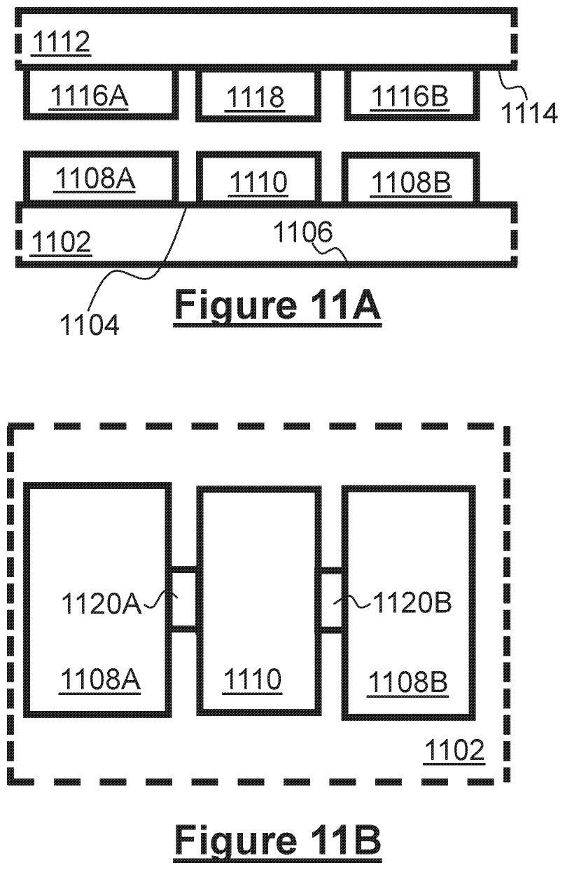

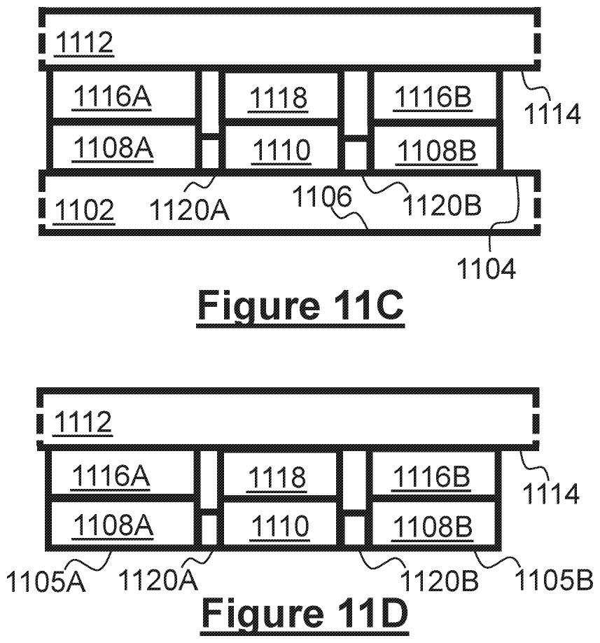

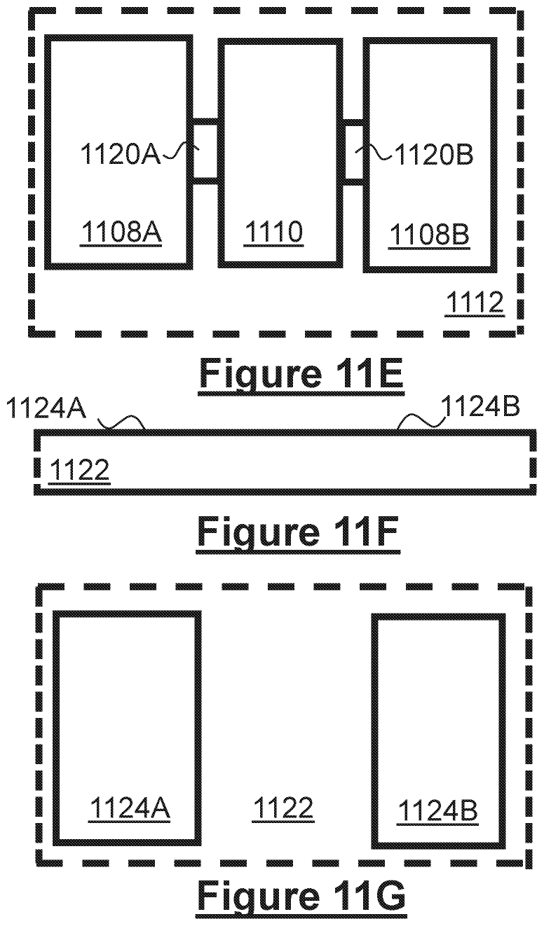

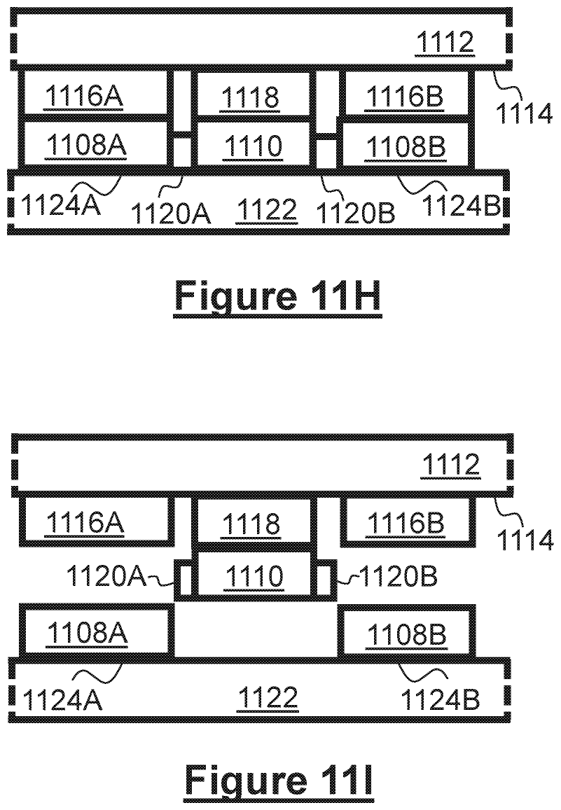

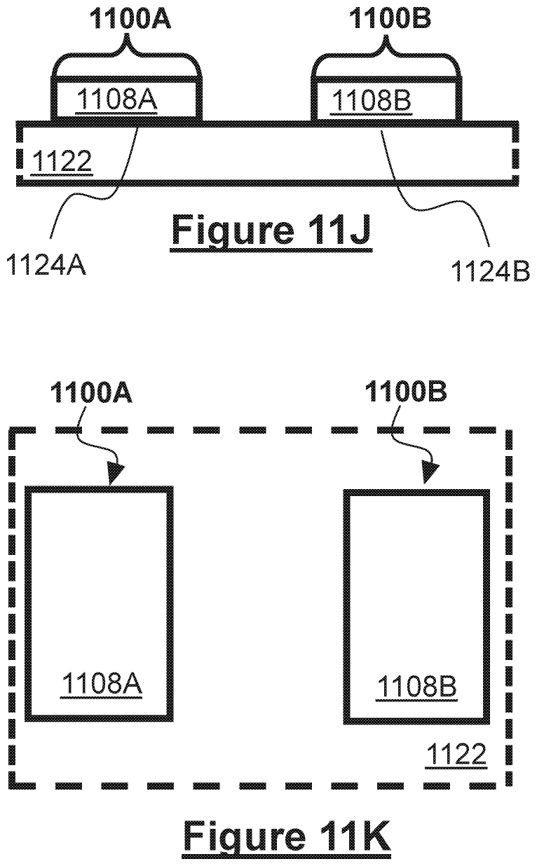

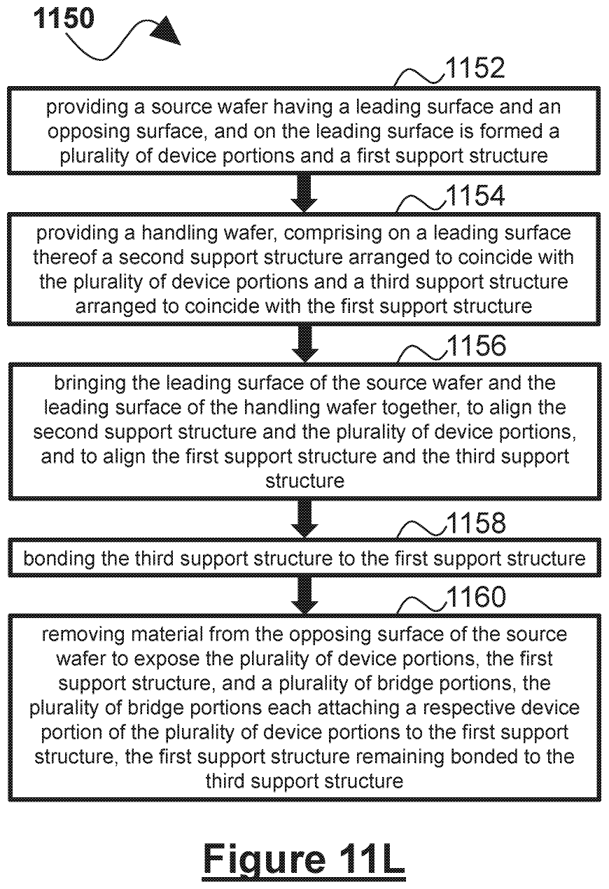

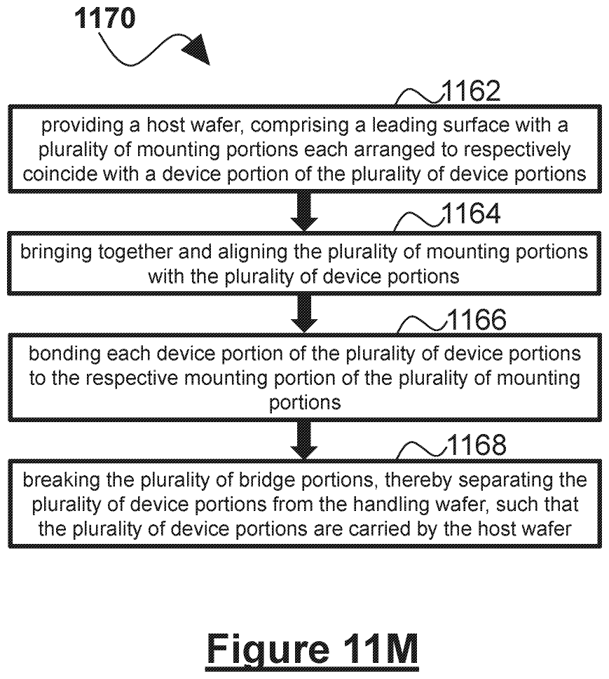

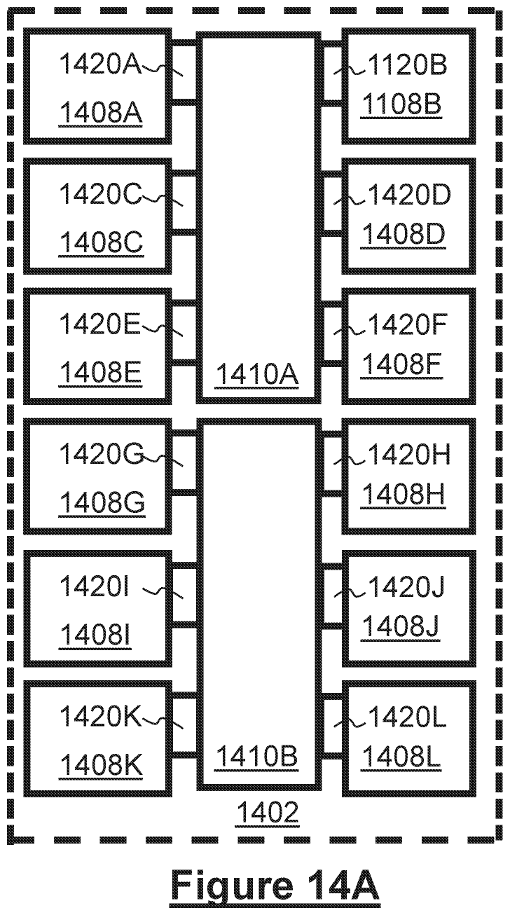

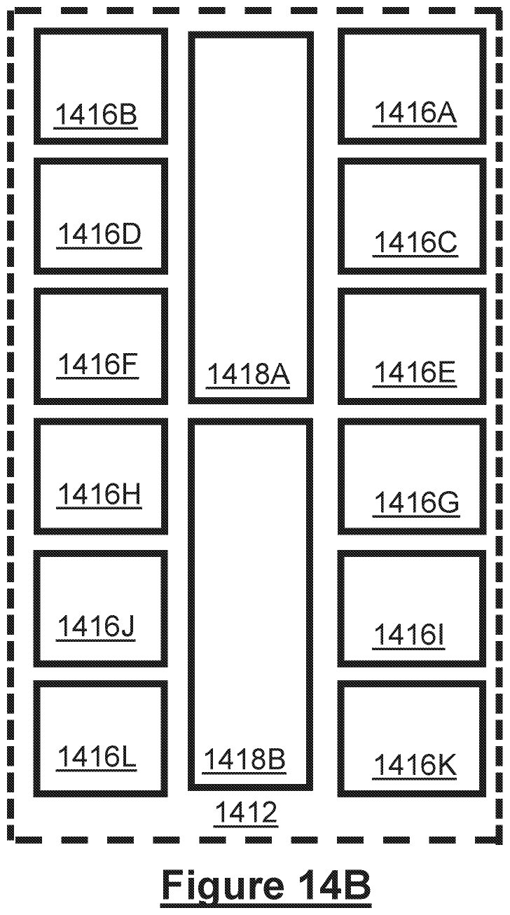

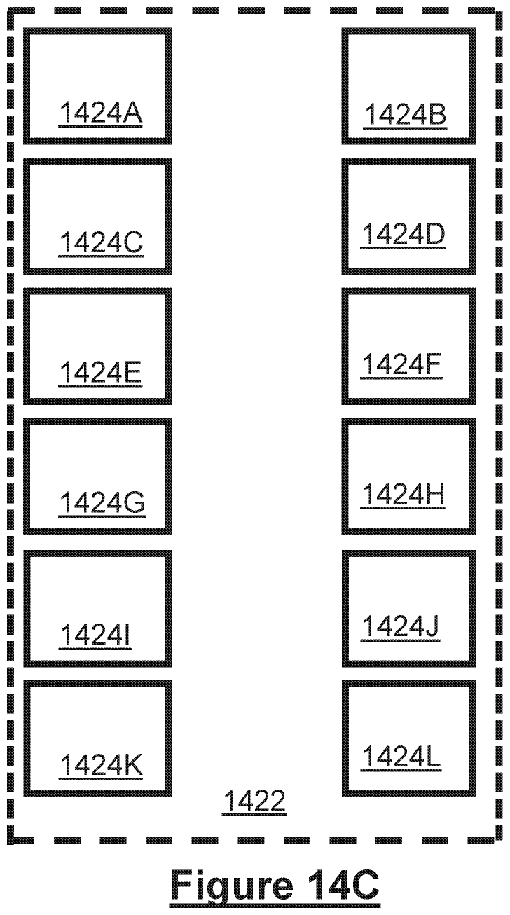

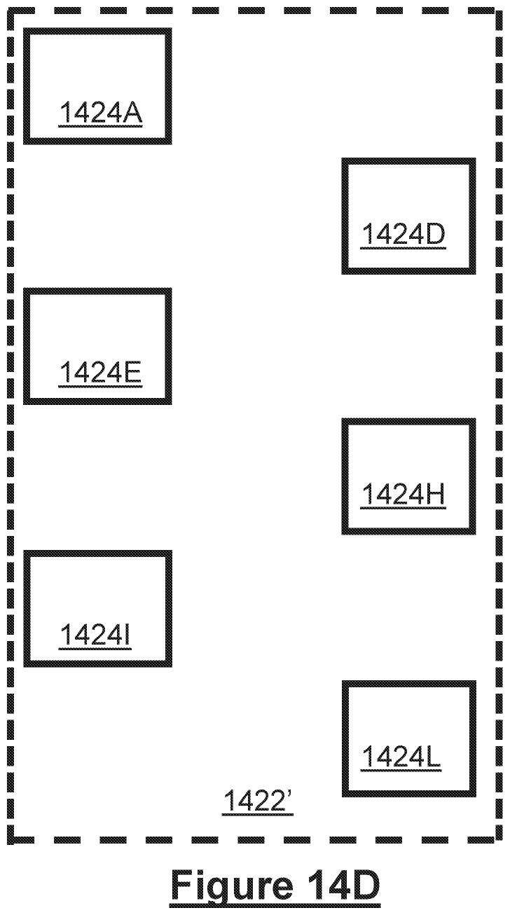

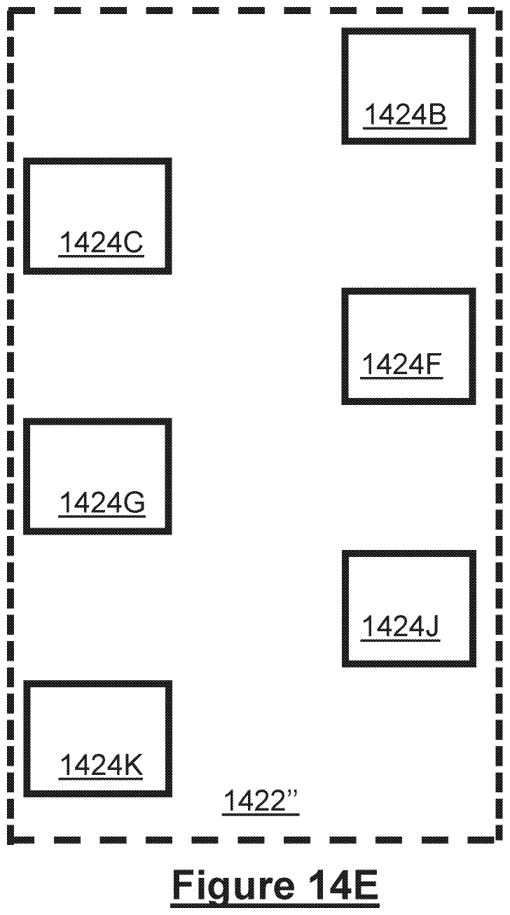

The examples herein will initially be described (with references to FIGS. 1A to 11B) in the context of a single device and/or device portion. The method may also apply to a plurality of devices and/or a plurality of device portions and especially to large numbers (for example, arrays) of devices and/or device portions. The later part of the description (with reference to FIGS. 11A to 13E) describes two devices and may apply to a large number of devices and/or device portions, as shown in FIGS. 14A to 14C.

In most cases, in the following description, the specific nature of a device or device portion is not important to an understanding of the disclosure, and details of how the device or device portions are formed on a source wafer (for example, using various stages including adding or removing materials) are not provided.

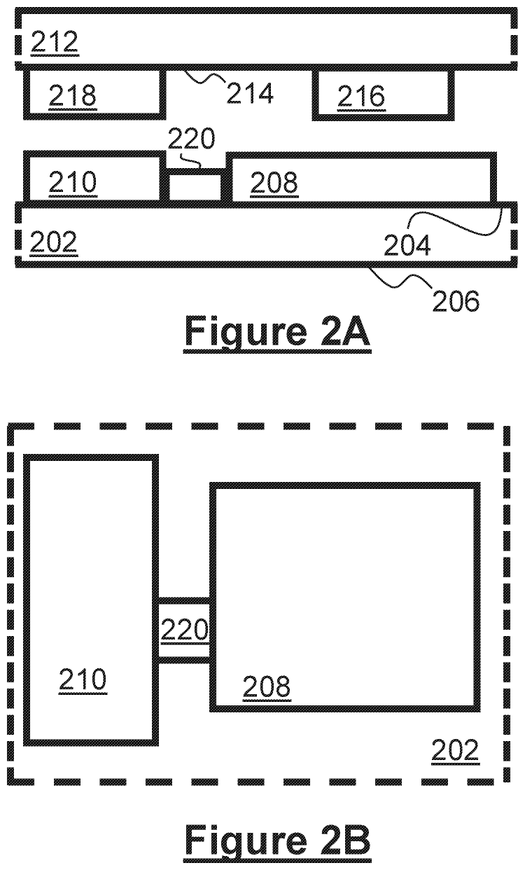

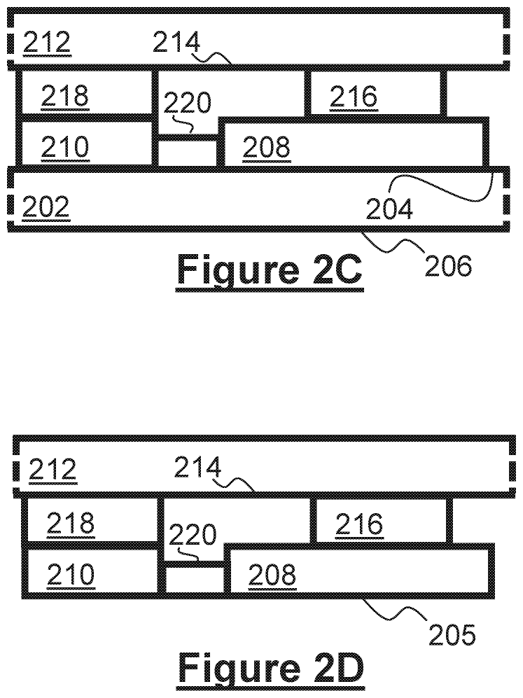

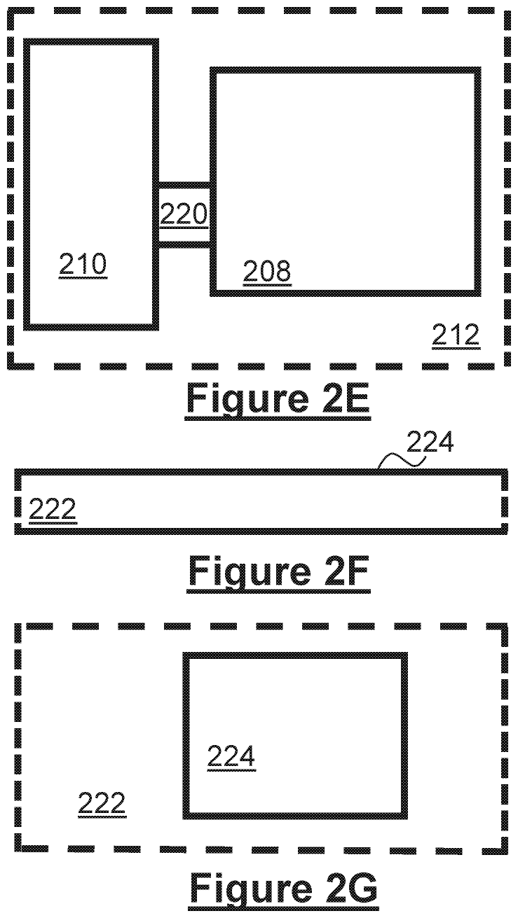

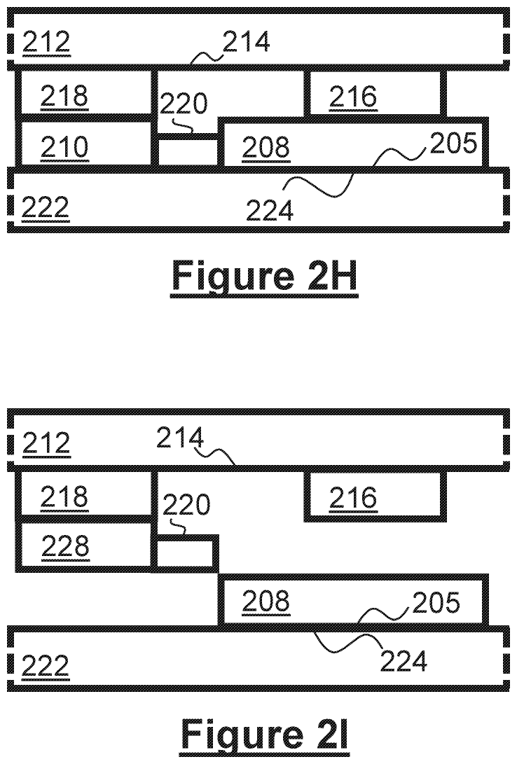

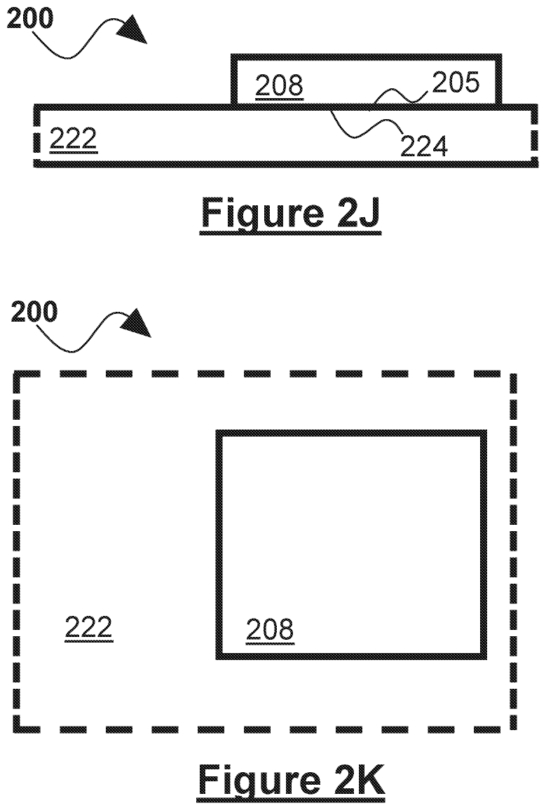

FIG. 1A illustrates a method 100 of assembling a device according to examples herein. The FIGS. 2A, 2C, and 2D are schematic block diagrams that each illustrate a first side cross-section of sequential stages of the method of FIG. 1A. FIG. 2B, and 2E are schematic block diagrams that illustrate a plan view of FIGS. 2A and 2D, respectively. With reference to FIGS. 1A to 2E, the method 100 comprises a block 102 of providing (FIGS. 2A and 2B) a source wafer 202 having a leading surface 204 and an opposing surface 206. On the leading surface 204 is formed a device portion 208 and a support portion 210. The device portion 208 and the support portion 210 are attached or connected to one another by a bridge portion 220, which, in this example, comprises source wafer 202 material in a region adjoining the device portion 208 and the support portion 210. In other examples, the bridge portion 220 may be formed from another material. The method then comprises a block 104 of providing (FIG. 2A) a handling wafer 212. The handling wafer 212 comprises on a leading surface 214 thereof a first support element 216, arranged to coincide with the device portion 208, and a second support element 218, arranged to coincide with the support portion 210. Then, the method 100 comprises a block 106 of bringing together (see the transition from FIGS. 2A and 2B to 2C) the leading surface 204 of the source wafer 202 and the leading surface 214 of the handling wafer 212. Further, bringing together comprises aligning the first support element 216 and the device portion 208, and aligning the second support element 218 and the support portion 210. Then the method comprises a block 108 of bonding (FIG. 2C) the second support element 218 of the handling wafer 212 to the support portion 210 of the source wafer 202. The method then comprises a block 110 of removing (see the transition from FIGS. 2C to 2D and 2E) material from the opposing surface 206 of the source wafer 202 to expose the device portion 208, the support portion 210, and the bridge portion 220. In practice, respective surfaces 205 or sides of the device portion 208, the support portion 210, and the bridge portion 220, which coincided with or were on the leading surface 204 of the source wafer 202, may be exposed, in this and in other examples hereafter. The bridge portion 220 attaches the device portion 208 to the support portion 210 (FIGS. 2A to 2E). The support portion 210 remains bonded to the second support element 218 during the removing 110 of material from the opposing surface 206 of the source wafer (see FIG. 2D).

In the examples of FIG. 2C and the transition from FIGS. 2C to 2D, the device portion 208 is supported by the first support element during bonding 108 (FIG. 2C), and when removing 110 (the transition from FIGS. 2C to 2D). In this context, ‘support’ can be provided by contact or near contact between the device portion 208 and the first support element 216, for instance, to mitigate the risk of cracking the source wafer 202 in the vicinity of the device portion 208 if pressure is applied to the opposing surface 206 of the source wafter. The bridge portion 220 continues to attach the device portion 208 to the support portion 210 and the support portion 210 remains bonded to the second support element 218. In this way, the handling wafer 212 also continues to provide indirect support to the device portion 208 (via the bridge portion 220, the support portion 210 and the second support element 218) even though the device portion 208 is not attached, or at least is not strongly attached, to the first support element 216. This support between the handling wafer 212 and the device portion 208 assists to maintain the spatial position of the device portion 208, relative to all other elements that are attached to the source wafer 202, handling wafer 212 and, latterly, the host wafer 222. In other examples, the device portion 208 is supported by the first support element 216 during only one or none of the blocks of: bonding 108 (FIG. 2C) or removing 110 (the transition from FIGS. 2C to 2D).

FIG. 1B illustrates additional stages 150 following those of the method 100 illustrated in FIG. 1A. FIGS. 2F, 2H and 21 are schematic block diagrams that each illustrate a first side cross-section of the additional stages 150. FIG. 2G is a schematic block diagram that illustrates a plan view of FIG. 2F. The additional stages 150 comprise a block 112 of providing (FIGS. 2F and 2G) a host wafer 222, comprising a leading surface with a mounting portion 224 arranged to coincide with the device portion 208. In some examples, the mounting portion 224 is a portion or region of the host wafer 222 and, in other examples (not illustrated), the mounting portion 224 may be raised from and/or recessed into the leading surface of the host wafer 222. Then, a block 114 comprises bringing together and aligning (the transition from FIGS. 2F and 2G to 2H) the mounting portion 224 of the host wafer 222 with the device portion 208. The method then comprises a block 116 of bonding (FIG. 2H) the device portion 208 to the mounting portion 224, and a block 118 of breaking (the transition from FIGS. 2H to 2I) the bridge portion 220, thereby separating the device portion 208 from the handling wafer 212. The bonding 116 and breaking 118 are such that the device portion 208 is carried by the host wafer 222 (see FIGS. 2J and 2K). The broken bridge portion (not shown) may be on the second support element and/or on the host wafer.

The device portion 208 is supported by the first support element 216 at various stages, for example when: providing 112 (FIGS. 2F and 2G); bringing together and aligning 114 (the transition from FIGS. 2F and 2G to 2H); bonding 116 (FIG. 2H); and breaking 118 (the transition from FIGA. 2H to 2I).

FIGS. 2J and 2K illustrate schematically, in accordance with examples, a device 200 obtained by the foregoing methods 100 and 150. In this example, the device comprises the host wafer 222, the mounting portion 224 and the device portion 208.

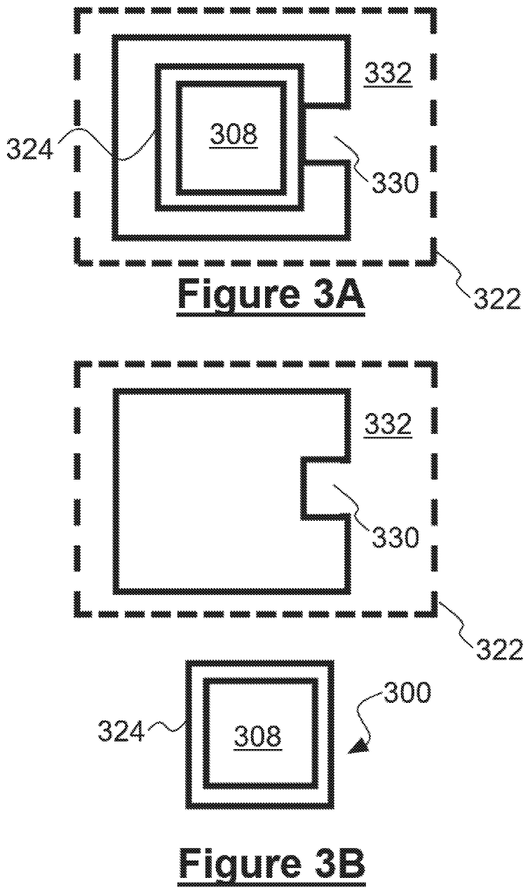

Further examples are now described with reference to FIGS. 3A and 3B, which are schematic block diagrams that each illustrate a plan view of sequential stages of a method according to further examples. FIG. 3B also illustrates a device 300 produced by methods described herein. A host wafer 322 comprises a handling portion 332 and a bridge element 330, the bridge element 330 connecting a mounting portion 324 to the handling portion 332. The method comprises breaking (the transition from FIG. 3A to FIG. 3B) the bridge element 330, thereby separating the handling portion 332 from the mounting portion 324 and a device portion 308. Breaking the bridge element 330, for example, may be achieved by: dicing the host wafer 322; applying a mechanical force, directly or indirectly, to the handling portion 332, the bridge element 330 and/or the mounting portion 324; lithography; a chemical process such as etching; or an electrostatic process. Features of the examples of FIG. 3 are similar to features described herein with reference to FIGS. 2A to 2K and are referred to using reference numerals 100 greater than those used for FIGS. 2A to 2K. Corresponding descriptions for such features apply here also.

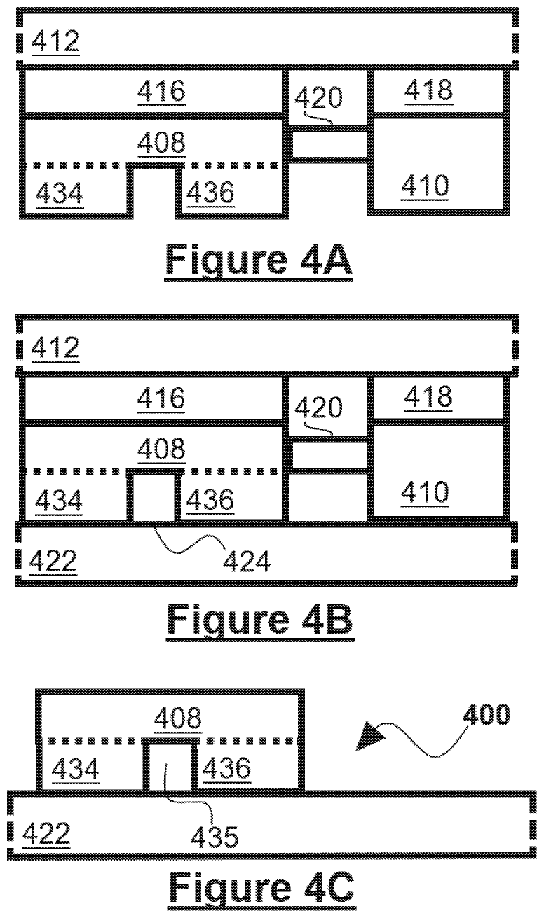

FIGS. 4A to 4C illustrate schematically stages of a method according to further examples, and FIG. 4C also illustrates a device 400 made by the method. FIG. 4A illustrates a device portion 408 comprising a first support member 434 and a second support member 436. The device portion 408 is aligned to a first support element 416 and attached to a support portion 410 by a bridge portion 420. A second support element 418 of the handling wafer 412 is bonded to the support portion 410. The method comprises aligning and bringing together (the transition between FIGS. 4A and 4B) a mounting portion 424 of a host wafer 422 with the device portion 408 comprises aligning and bringing together the mounting portion 424 of the host wafer 422 with the first support member 434 and the second support member 436. Then, bonding (FIG. 4B) the device portion 408 to the mounting portion 424 comprises bonding the first support member 434 and the second support member 436 to the mounting portion 424 to form a MEMS 400, shown in FIG. 4C. Features of the examples of FIGS. 4A to 4C are similar to features described herein with reference to FIGS. 2A to 2K and are referred to using reference numerals 200 greater than those used for FIGS. 2A to 2K. Corresponding descriptions for such features apply here also. The MEMS 400, for example, may be a membrane sensor. The method may allow forming of a membrane sensor without using conventional techniques such as a vapour undercut. Such a MEMS has a cavity 435. The cavity 435 of the MEMS 400 can contain different materials, for example as determined by conditions during bonding of the first support member 434 and the second support member 436 to the mounting portion 424. In other examples, by bonding under vacuum conditions, the cavity 435 may be under a vacuum. In other examples, the cavity 435 may contain air, a gas or a mix of gasses. Control of the material in the cavity 435 provides control over the functionality of the MEMS 400.

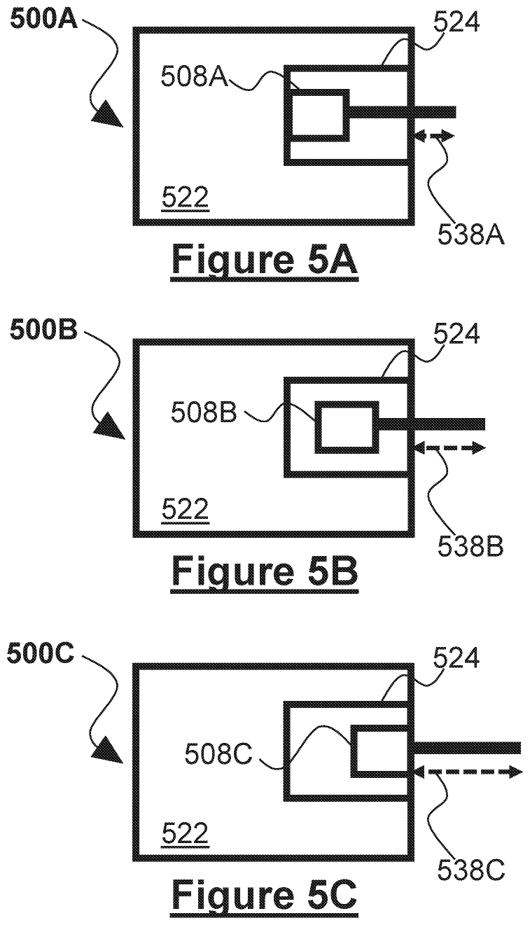

FIGS. 5A to 5C each illustrate, in accordance with further examples, devices 500A, 500B and 500C obtained by the foregoing methods. In FIGS. 5A to 5C, the device portions 508A, 508B and 508C are respectively in three different positions on a mounting portion 524. The positioning of the device portion 508A, 508B and 508C on the mounting portion 524 of a host wafer 522 can affect the properties of the devices 500A, 500B and 500C. In particular, as shown, the extension of the device portion 508A, 508B and 508C from the host wafer 522 (to the right-hand side of the Figures) depends on the positioning of the device portion 508A, 508B and 508C on the mounting portion 524. For example, when assembling an AFM probe device, the method can be used to provide AFM probes with cantilevers of different lengths 538A, 538B and 538C. Beneficially, the method described herein may provide AFM probes with multiple cantilevers lengths. In some examples, this allows AFM probes with different properties to be assembled rapidly and/or a single AFM device to be assembled with multiple different properties. Features of the examples of FIG. 5 are similar to features described herein with reference to FIGS. 2A to 2K and are referred to using a reference numeral 300 greater than those used for FIGS. 2A to 2K. Corresponding descriptions for such features apply here also.

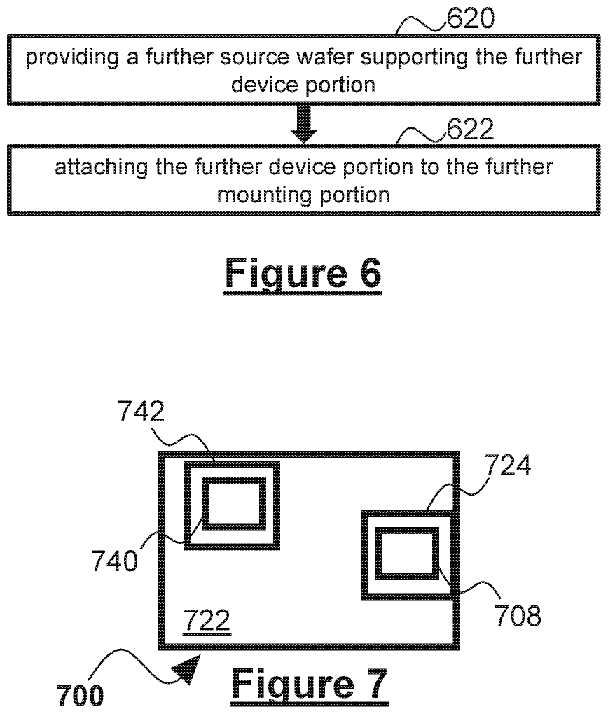

FIGS. 6 and 7 illustrate further examples described herein. FIG. 6 is a flow diagram that illustrates schematically blocks 620 and 622 of a method 600 following the method 150 of FIG. 1B. FIG. 7 shows a device 700 made using the method 150 of FIG. 1B then the blocks 620 and 622 of FIG. 6. A further source wafer is provided 620. The further support wafer supporting a further device portion. The further device portion is then attached 622 to the further mounting portion. Blocks 620 and 622 in some examples provide a device 700. The device 700 comprises the host wafer 722. The first mounting portion 724 and the second mounting portion 742 are supported by the host wafer 722. The second device portion 740 is attached to the second mounting portion 742. Features of the examples of FIG. 7 are similar to features described herein with reference to FIGS. 2J and 2K and are referred to using reference numerals 500 greater than those used for FIGS. 2J and 2K. Corresponding descriptions for such features apply here also.

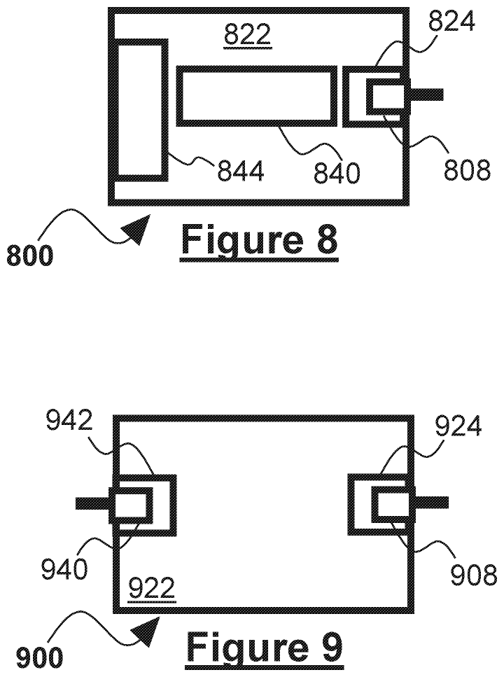

FIG. 8 illustrates, in accordance with further examples, a device 800 that is obtained by the method 600 (illustrated in FIG. 6). The device 800 comprises a host wafer 822 and a first mounting portion 824. A first device portion 808 is attached to the first mounting portion 824. The device 800 further comprises a second device portion 840 and a third device portion 844 on the host wafer 822. The first device portion 808, the second device portion 840 and the third device portion 844 are different from one another. For example, the first device portion 808 is an AFM probe, the second device portion 840 is a clip point and/or conductive pad, and the third device portion 844 is an identifier. Other arrangements of different devices can be formed according to other examples. Features of the examples of FIG. 8 are similar to features described herein with reference to FIGS. 2J and 2K and are referred to using reference numerals 600 greater than those used for FIGS. 2J and 2K. Corresponding descriptions for such features apply here also.

FIG. 9 illustrates, in accordance with further examples, a device 900 that is obtained by the method 600 of FIG. 6. The device 900 comprises a host wafer 922 and a first mounting portion 924. A first device portion 908 is bonded to the first mounting portion 924. The device 900 further comprises aa second mounting portion 942. A second device portion 940 is attached to the second mounting portion 942 In this example, the first device portion 908 is a first AFM probe. The second device portion 940 is a second AFM probe. The inclusion of a plurality of AFM probes may allow the device to be used when the first probe is no longer usable or may allow a single device to provide two different AFM probes with different functionalities. Features of the examples of FIG. 9 are similar to features described herein with reference to FIGS. 2J and 2K and are referred to using reference numerals 700 greater than those used for FIGS. 2J and 2K. Corresponding descriptions for such features apply here also.

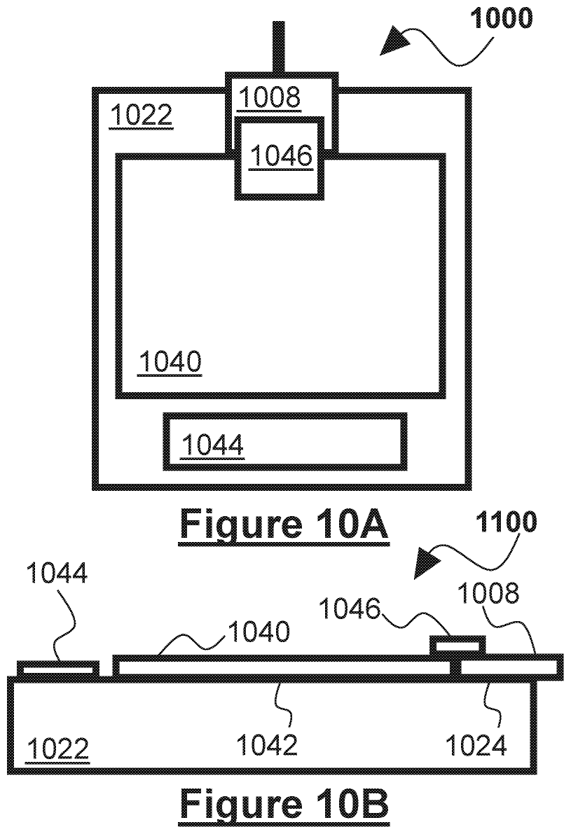

FIG. 10 illustrates, in accordance with further examples, a device 1000 that is obtained by the method 600 of FIG. 6. In such examples, the device 1000 comprises a host wafer 1022, a first device portion 1008, a second device portion 1040, a third device portion 1044, and a fourth device portion 1046. The first device portion 1008, the second device portion 1040, the third device portion 1044, and fourth device portion 1046 are different from each other. the first device portion 1008 may be an AFM probe. The second device portion 1040 may be a clip point and/or a conductive pad. The third device portion 1044 may be a device portion configured to perform a further functionality, such as identification. The fourth device portion 1046 may be a conductive bridge. A conductive bridge 1046 is for electrically connecting an AFM probe 1008 and a clip point and/or a conductive pad 1044. Features of the examples of FIG. 10 are similar to features described herein with reference to FIGS. 2J and 2K and are referred to using reference numerals 800 greater than those used for FIGS. 2J and 2K. Corresponding descriptions for such features apply here also.

FIGS. 11A to 11M illustrate examples relating to assembly of a plurality of devices or a plurality of device portions. FIG. 11L is a flow diagram of a corresponding method. The method comprises a block 1152 of providing (FIGS. 11A and 11B) a source wafer 1102. The source wafer 1102 has a leading surface 1104 and an opposing surface 1106. A plurality of device portions 1108A and 1108B and a first support structure 1110 are formed on the leading surface. Next, the method comprises a block 1154 of providing (FIGS. 11A and 11B) a handling wafer 1112. A second support structure 1116A and 1116B is on the leading surface 1114 of the handling wafer 1112. The second support structure 1116A and 1116B comprises a plurality of support elements 1116A and 1116B. Each of the plurality of support elements 1116A and 1116B of the second support structure 1116A and 1116B are respectively arranged to coincide with the plurality of device portions 1108A and 1108B. The handling wafer 1112 also comprises on the leading surface 1114 thereof a third support structure 1118. The third support structure 1118 is arranged to coincide with the first support structure 1110. Next, the method comprises a block 1156 of bringing together (the transition from FIG. 11A to 11C) the leading surface 1104 of the source wafer 1102 and the leading surface 1114 of the handling wafer 1112, as well as aligning the plurality of support elements 1116A and 1116B of the second support structure and the plurality of device portions 1108A and 1108B, and aligning the third support structure 1118 and the first support structure 1110. Next, the method comprises a block 1158 of bonding (FIG. 11C) the third support structure 1118 of the handling wafer 1112 to the first support structure 1110 of the source wafer 1102. The method then comprises a block 1160 of removing (see the transitions from FIG. 11C to 11D and 11E) material from the opposing surface 1106 of the source wafer 1102 to expose each device portion of the plurality of device portions 1108A and 1108B, the first support structure 1110, and a plurality of bridge portions 1120A and 1120B. In practice, respective surfaces 1105A and 1105B or sides of the plurality of device portions 1108A and 1108B, the first support structure 1110, and the plurality of the bridge portions 1120A and 1120B, which coincided with or were on the leading surface 1104 of the source wafer 1102, may be exposed, The plurality of bridge portions 1120A and 1120B each respectively attach a device portion of the plurality of device portions 1108A and 1108B to the first support structure 1110. The first support structure 1110 remains bonded to the third support structure 1118. In this example, the first support structure 1110 portion is a single element. In other examples, the first support structure comprises a plurality of individual elements each for bonding to a respective element of a plurality of elements of the third support structure support.

FIG. 11L illustrates additional stages 1170 following those of the method 1150 illustrated in FIG. 11L. In a next stage, a block 1162 comprises providing a host wafer 1122 (FIGS. 11F and 11G). The host wafer 1122 comprises a leading surface with a plurality of mounting portions 1124A and 1124B each arranged to respectively coincide with a device portion of the plurality of device portions 1108A and 1108B. The method then comprises a block 1164 of bringing together and aligning (the transition from FIGS. 11D to 11G to 11H) the plurality of mounting portions 1124A and 1124B of the host wafer 1122 with the plurality of device portions 1108A and 1108B. The method then comprises a block 1166 of bonding (FIG. 11H) each device portion of the plurality of device portions 1108A and 1108B to the respective mounting portion of the plurality of mounting portions 1124A and 1124B. Then a block 1168 comprises breaking (the transition from FIG. 11H to 11I) the plurality of bridge portions 1120A and 1120B, thereby separating the plurality of device portions 1108A and 1108B from the handling wafer 1112, such that the plurality of device portions 1108A and 1108B are carried by the host wafer 1122.

FIGS. 11J and 11K schematically illustrate a plurality of devices 1100A and 1100B assembled by the method 1100 described above for FIGS. 11A to 11I, 11L and 11M.

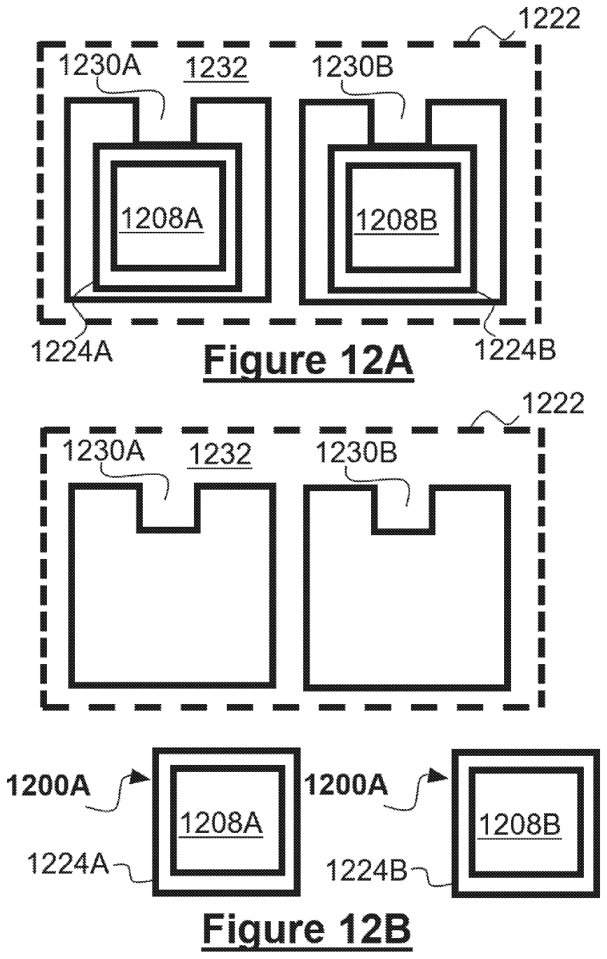

In some examples, such as those illustrated in FIGS. 12A and 12B, the host wafer 1222 comprises a handling portion 1232 and a plurality of bridge elements 1230A and 1230B. The plurality of bridge elements 1230A and 1230B each respectively connecting a mounting portion of the plurality of mounting portions 1224A and 12B to the handling portion 1232. The method further comprises breaking (the transition from FIGS. 12A to 12B) the plurality of bridge elements 1230A and 1230B, thereby separating the handling portion 1232 from the plurality of mounting portions 1224A and 1224B and the plurality of device portions 1208A and 1208B. Features of the examples of FIGS. 12A and 12B are similar to features described herein with reference to FIGS. 11A and 11K and are referred to using reference numerals 100 greater than those used for FIGS. 11A and 11K. Corresponding descriptions for such features apply here also.

Similar to FIG. 4C, in relation to a single device, each of the plurality of devices as described above may be a MEMS. Such a plurality of MEMSs may be formed by a method as described above for FIGS. 11A to 11M.

The device 1108A and 1108B portions are of equal height/thickness measured perpendicular to the respective mounting portion 1124A and 1124B. However, as described in later examples, the heights/thicknesses may be different. The support elements 1116a and 1116B of the second support structure of the examples of are of equal height/thickness measured perpendicular to the leading surface 1114 of the handling wafer 1112. However, as described in later examples, the heights/thicknesses may be different.

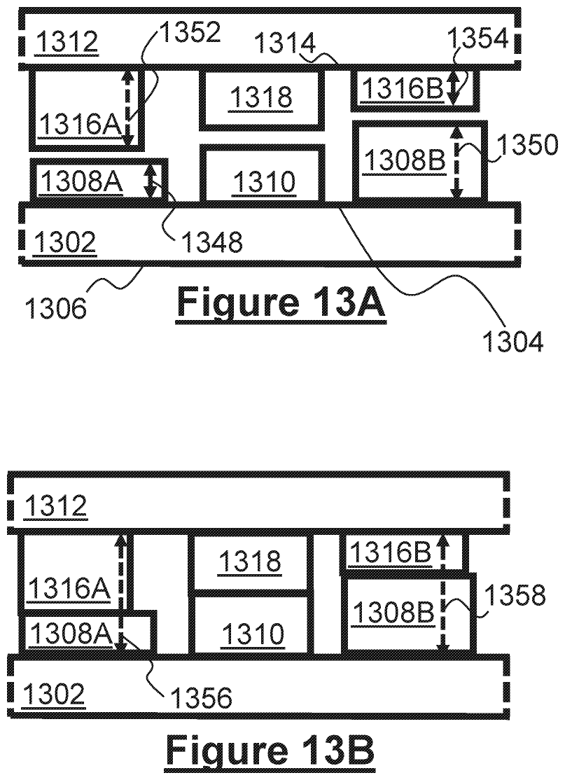

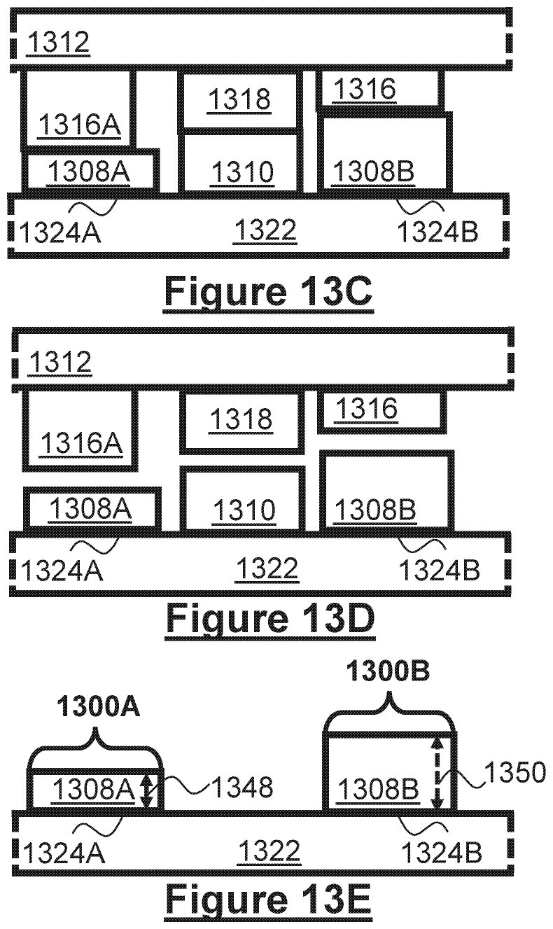

FIGS. 13A to 13D illustrate further examples of the method described herein wherein the plurality of device portions are not of equal thicknesses. The source wafer 1302 has a leading surface 1304 and an opposing surface 1306. A plurality of device portions 1308A and 1308B and the first support structure 1310 are formed on the leading surface 1304. A thickness 1348 of a first device portion 1308A of the plurality of device portions is different to a thickness 1305 of a second device portion 1308B of the plurality of device portions. In some such examples (as illustrated in FIG. 13A), the handling wafer 1312 comprises, on a leading surface 1314 thereof, a second support structure 1316A and 1316B. The second support structure 1316A and 1316B comprises a plurality of support elements 1316A and 1316B. The plurality of first support elements 1316A and 1316B are arranged, in terms of their positions and their thicknesses, to respectively coincide with the plurality of device portions 1308A and 1308B. More particularly, the thickness 1352 of a first support element 1316A of the second support structure 1316A and 1316B is different to the thickness 1354 of a support element 1316B of the second support structure 1316A and 1316B, to accommodate the different thicknesses of the device portions 1308A and 1308B. The handling wafer 1312 further comprises, on the leading surface 1314 thereof, a second support element 1318 that is arranged to coincide with the support portion 1310. Each thickness is measured perpendicularly the leading surface 1314 of the handling wafer 1312.

The plurality of device portions 1308A and 1308B may be, respectively, supported by a first support element of the plurality of first support elements 1316A and 1316B while: bonding the second support element 1318 of the handling wafer 1312 to the support portion 1310 of the source wafer 1303 (FIG. 13B); bonding each device portion of the plurality of device portions 1308A and 1308B to the respective mounting portion of the plurality of mounting portions 1324A and 1324B (FIG. 13C); and/or breaking the plurality of bridge portions, thereby separating the plurality of device portions 1308A and 1308B from the handling wafer 1312, such that the plurality of device portions 1308A and 1308B are carried by the host wafer 1322 (transition from FIG. 13C to FIG. 13D).

As can be seen in the example shown in FIGS. 13A and 13B, the sum 1356 of the thickness 1348 of the first device portion 1308A of the plurality of device portions, and the thickness 1352 of the primary first support element 1316A of the plurality of first support elements, is equal to the sum 1358 of the thickness 1350 of the second device portion 1308B of the plurality of device portions, and the thickness 1354 of the secondary first support element 1316B of the plurality of first support elements.

FIG. 13E illustrates a plurality of devices 1300A and 1300B, assembled or fabricated by the method of examples described in relation to FIGS. 13A to 13D above. Features of the examples of FIGS. 13A to 13F are similar to features described herein with reference to FIGS. 11A to 11K and are referred to using reference numerals 200 greater than those used for FIGS. 11A to 11K. Corresponding descriptions for such features apply here also.

FIGS. 14A to 14C illustrate examples relating to a plurality or array of device portions. The method of production is similar to that described above with reference to FIGS. 1A to 2K for a device and a device portion shown in FIGS. 11A to 11L for a plurality of device portions.

FIG. 14A is a schematic block diagram that illustrates a plan view of a source wafer 1402 according to examples. The source wafer 1402 has a plurality or array of device portions 1408A to 1408L and a first support structure 1410A and 1410B on its leading surface. The support portion 1410 comprise a plurality of support elements 1410A and 1410B. A plurality or array of bridge portions 1420A to 1420L attach the plurality or array of device portions 1408A to 1408L to the first support structure 1410A and 1410B.

FIG. 14B is a schematic block diagram that illustrates a plan view of a handling wafer 1412 according to examples. The handling wafer 1412 has a second support structure 1416A to 1416L comprising a plurality of support elements 1416A to 1416L and a third support element 1418A and 1418B comprising a plurality of support elements 1418A and 1418B. Both the second support structure 1416A to 1416L and the third support structure 1418A and 1418B are on the leading surface of the handling wafer 1412.

FIG. 14C is a schematic block diagram that illustrates a plan view of a host wafer 1422 according to examples. The host wafer 1422 has a plurality or array of mounting portions 1424A to 1424L on its leading surface arranged to coincide with the device portions 1408A to 1408L.

In the examples illustrated by FIGS. 14A and 14C the method comprises bringing the leading surface of the source wafer 1402 (FIG. 14A) and the leading surface of the handling wafer 1412 (FIG. 14B) together. Bringing the leading surface of the source wafer 1402 and the leading surface of the handling wafer 1412 together may comprise inverting the source wafer 1402 and/or the handling wafer 1412. The method then comprises bonding the first support structure 1410A and 1410B and the third support structure 1418A and 1418B. Next, the method comprises removing material from the opposing surface of the source wafer 1402 to expose each device portion of the plurality of device portions 1408A to 1408L, the first support structure 1410A and 1410B, and the plurality of bridge portions 1420A to 1420L. In the further examples of the method, the method comprises bringing together and aligning the plurality of mounting portions 1424A to 1424L of the host wafer 1422 (illustrated in FIG. 14C) with the plurality of device portions 1408A to 1408L. The method then comprises bonding each device portion of the plurality of device portions 1408A to 1408L to the respective mounting portion of the plurality of mounting portions 1424A to 1424L. Next, the method comprises breaking the plurality of bridge portions 1420A to 1420L, thereby separating the plurality of device portions 1408A to 1408L from the handling wafer 1412, such that the plurality of device portions 1408A to 1408L are carried by the host wafer 1422. Features of the examples of FIG. 14A to 14C are similar to features described herein with reference to FIG. 11A to 11M and are referred to using reference numerals 300 greater than those used for FIGS. 11A to 11M. Corresponding descriptions for such features apply here also.

FIGS. 14D and 14E are plan views of an alternative arrangement of two host wafers 1422′, 1422″, according to examples, which can be used instead of the host wafer 1422. In this case, a first host wafer 1422′ has a plurality or array of mounting portions 1422A, 1422D, 1422E, 1422H, 1422I and 1422L, and a second host wafer 1422″ has a plurality or array of mounting portions 1422B, 1422C, 1422F, 1422G, 1422J and 1422K. The mounting portions of the first host wafer 1422′ coincide with respective device portions 1408A, 11408D, 1408E, 1408H, 1408I and 1408L, and the mounting portions of the second host wafer 1422″ coincide with respective device portions 1408B, 1408C, 1408F, 1408G, 1408J and 1408K. In this way, the device portions 1408 may be formed in a relatively densely packed array or arrangement and then may be mounted on each of a plurality of host wafers in a relatively less-densely-packed arrangement. Different less-densely-packed arrangements can be selected according to the number and arrangement of host wafers. In such examples, two or more host wafers may be employed, and the arrangements of device portions on the host wafers may be selected for any appropriate requirement. For example, ten host wafers could be employed, each attaching to a different arrangement of one in every ten device portions, thereby to reduce the density of the device portions on the host wafer by a factor of 10. Of course, any other arrangement and reduction of density may be employed. In any event, accurate alignment of the device portions on the host wafter(s) is ensured, according to the techniques described herein.

As the skilled person will appreciate, various techniques may be used to form, fabricate, provide, or supply a wafer, an element, a portion, or a member in accordance with examples described herein. As will be appreciated, the various structural features of each example described herein can be formed using techniques known to the skilled person. Examples of such techniques for at least partially forming a surface, a grating, a substrate, a waveguide, a semiconductor and/or or an electrode are: lithography, chemical vapor deposition, atomic layer deposition, physical vapor deposition, molecular beam epitaxy, laser lift-off, electrochemical deposition, electroplating, diffusion, epitaxy, surface passivation, photolithography, ion implantation, etching, dry etching, ion etching, wet etching, buffered oxide etching, plasma ashing, thermal treatment, annealing, thermal oxidation, or chemical-mechanical polishing. In some examples etching techniques are used to remove portions of material, as part of patterning, as the skilled person will appreciate.

In the above description, reference is made to at least partly forming portions and the like. In some examples, a portion referred to in this manner is simply formed by depositing the relevant material, without requiring further steps. In other examples, further steps are performed to complete the formation of a portion (for example, a curing step, an etching step to define the extent of a layer, etc.). In some examples, the further steps to complete the formation of a portion are performed before further material is deposited on top of the portion in question. In other examples, the further steps to complete the formation of a portion are performed after further material is deposited on top of the portion in question.

In the described Figures, dashed lines are included at the edges of certain parts to indicate continuation of the parts in question beyond what is schematically illustrated in the Figures. In the described Figures, dotted lines are included at the boarders between certain regions of a part to indicate the boarders. The Figures include schematic illustrations of structures related to the described examples of the device. None of the Figures should be taken to indicate precise proportions with respect to any other Figure.

The above examples are to be understood as illustrative examples of the invention. It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the accompanying claims.

1. A method, comprising:
providing a source wafer having a leading surface and an opposing surface, and on the leading surface is formed a device portion and a support portion;
providing a handling wafer, comprising on a leading surface thereof a first support element arranged to coincide with the device portion and a second support element arranged to coincide with the support portion;
bringing the leading surface of the source wafer and the leading surface of the handling wafer together, to align the first support element and the device portion, and to align the second support element and the support portion;
bonding the second support element of the handling wafer to the support portion of the source wafer;
removing material from the opposing surface of the source wafer to expose the device portion, the support portion, and a bridge portion, the bridge portion attaching the device portion to the support portion, the support portion remaining bonded to the second support element.

2. The method of claim 1, comprising providing the device portion, and/or the first support element, such that the step of bonding the second support element of the handling wafer to the support portion of the source wafer causes no or at least reduced bonding of the device portion to the first support element.

3. (canceled)

4. The method of claim 1, comprising
providing a host wafer, comprising a leading surface with a mounting portion arranged to coincide with the device portion;
bringing together aligning the mounting portion with the device portion;
bonding the device portion to the mounting portion; and
breaking the bridge portion, thereby & the device portion from the handling wafer, such that the device portion is carried by the host wafer,
wherein bringing together and aligning the mounting portion with the device portion comprises optically imaging the device portion and at least part of the host wafer, the optical imaging being at least partly through the handling wafer.

5. The method of claim 1, comprising
providing a host wafer, comprising a leading surface with a mounting portion arranged to coincide with the device portion;
bringing together and aligning the mounting portion with the device portion;
bonding the device portion to the mounting portion; and
breaking the bridge portion, thereby & the device portion from the handling wafer, such that the device portion is carried by the host wafer, wherein:
the host wafer comprises handling portion and a bridge element, the bridge element connecting the mounting portion to the handling portion, and the method comprises breaking the bridge element, thereby separating the handling portion from the mounting portion and the device portion; or
the device portion comprises a first support member and a second support member, and the method comprises bonding the first support member and the second support member to the mounting portion to form a microelectromechanical system.

6. The method of claim 1, comprising
providing a host wafer, comprising a leading surface with a mounting portion arranged to coincide with the device portion;
bringing together and aligning the mounting portion with the device portion;
bonding the device portion to the mounting portion; and
breaking the bridge portion, thereby & the device portion from the handling wafer, such that the device portion is carried by the host wafer.
wherein a surface of the mounting portion comprises an optical reflector and/or an adhesive.

7. (canceled)

8. The method of claim 1, comprising
providing a host wafer, comprising a leading surface with a mounting portion arranged to coincide with the device portion;
bringing together and aligning the mounting portion with the device portion;
bonding the device portion to the mounting portion; and
breaking the bridge portion, thereby separating the device portion from the handling wafer, such that the device portion is carried by the host wafer,
wherein at least one of the device portion and the host wafer comprises at least part of a further mounting portion to receive a further device portion, the further device portion different to the device portion, and the method further comprises:
providing a further source wafer supporting the further device portion; and
attaching the further device portion to the further mounting portion.

9. A method, comprising:
providing a source wafer having a leading surface and an opposing surface, and on the leading surface is formed a plurality of device portions and a first support structure;
providing a handling wafer, comprising on a leading surface thereof a second support structure arranged to coincide with the plurality of device portions and a third support structure arranged to coincide with the first support structure;
bringing the leading surface of the source wafer and the leading surface of the handling wafer together, to align the second support structure and the plurality of device portions, and to align the first support structure and the third support structure;
bonding the third support structure to the first support structure;
removing material from the opposing surface of the source wafer to expose each device portion of the plurality of device portions, the first support structure, and a plurality of bridge portions, a plurality of bridge portions each attaching a respective device portion of the plurality of device portions to the first support structure, the first support structure remaining bonded to the third support structure.

10. The method of claim 9, comprising providing each device portion of the plurality of device portions, and/or the second support structure, such that the step of bonding the third support structure to the first support structure causes no or at least reduced bonding of the plurality of device portions to the second support structure.

11. The method of claim 10, comprising:
providing a host wafer, comprising a leading surface with a plurality of mounting portions each arranged to respectively coincide with a device portion of the plurality of device portions;
bringing together and aligning the plurality of mounting portions with the plurality of device portions;
bonding each device portion of the plurality of device portions to the respective mounting portion of the plurality of mounting portions;
breaking the plurality of bridge portions, thereby separating the plurality of device portions from the handling wafer, such that the plurality of device portions are carried by the host wafer.

12. The method of claim 11, wherein:
a thickness of a first device portion of the plurality of device portions is different to a thickness of a second device portion of the plurality of device portions, each thickness measured perpendicular to the respective mounting portion of the plurality of mounting portions.

13. The method of claim 12, wherein the second support structure comprises a plurality of support elements, each respectively arranged to coincide with a device portion of the plurality of device portions.

14. The method of claim 13, wherein:
a thickness of a first support element of the plurality of support elements of the second support structure, is different to a thickness of a second support element of the plurality of support elements of the second support structure, each thickness measured perpendicular to the leading surface of the handling wafer.

15. The method of claim 14, wherein the sum of:
the thickness of the first device portion of the plurality of device portions, and
the thickness of the first support element of the plurality of support elements of the second support structure,
is equal to the sum of the thickness of the second device portion of the plurality of device portions, and the thickness of the second support element of the plurality of support elements of the second support structure.

16. The method of claim 11, wherein at least one of the plurality of device portions or the host wafer comprises at least part of a plurality of further mounting portions each respectively to receive a further device portion of a plurality of further device portions, the plurality of further device portions different to the plurality of device portions, and the method further comprises:
providing a further source wafer supporting the plurality of further device portions; and
respectively attaching each of the plurality of further device portions to a mounting portion of the further mounting portion.

17. The method of claim 11, wherein each of the plurality of device portions comprise a first support member and a second support member, and the method comprises bonding each of the first support members and the second support members to the respective mounting portions of the plurality of mounting portions to form a plurality of microelectromechanical systems.

18. The method of claim 11, wherein bringing together and aligning the plurality of mounting portions with the plurality of device portions, comprises optically imaging a device portion of the plurality of device portions and at least part of the host wafer, the optical imaging at least partly through the handling wafer.

19. The method of claim 11, wherein the host wafer comprises handling portion and a plurality of bridge elements, the plurality of bridge elements each respectively connecting a mounting portion of the plurality of mounting portions to the handling portion, and the method comprises breaking the plurality of bridge elements, thereby separating the handling portion from the plurality of mounting portions and the plurality of device portions.

20. The method of claim 11, wherein a surface of each mounting portion of the plurality of mounting portions respectively comprises an optical reflector and/or an adhesive.

21. The method of claim 9, wherein the first support structure comprises a plurality of support elements and the third support structure comprises a plurality of support elements, and the plurality of support elements of the first support structure are each respectively arranged to coincide with a support element of the third support structure.

22.-25. (canceled)

26. A method of assembling an atomic force microscopy probe device, the method comprising:
providing a source wafer having a leading surface and an opposing surface, and on the leading surface is formed a device portion and a support portion;
providing a handling wafer, comprising on a leading surface thereof a first support element arranged to coincide with the device portion and a second support element arranged to coincide with the support portion;
bringing the leading surface of the source wafer and the leading surface of the handling wafer together, to align the first support element and the device portion, and to align the second support element and the support portion;
bonding the second support element of the handling wafer to the support portion of the source wafer;
removing material from the opposing surface of the source wafer to expose the device portion, the support portion, and a bridge portion, the bridge portion attaching the device portion to the support portion, the support portion remaining bonded to the second support element.
